(19) United States
(12) Patent Application Publication
(10) Pub. No.: US 2026/0251722 A1
(43) Pub. Date: Aug. 27, 2026

(54) CALIBRATION METHOD OF BATTERY ELECTRONIC CONTROL UNIT

(71) Applicant: TOYOTA JIDOSHA KABUSHIKI KAISHA, Toyota-shi (JP)

(72) Inventors: Hiroki TASHIRO, Toyota-shi (JP); Yoshiaki KIKUCHI, Toyota-shi (JP); Ryo MANO, Toyota-shi (JP); Yuji NISHI, Toyota-shi (JP); Keisuke ISHIKAWA, Nagakute-shi (JP)

(73) Assignee: TOYOTA JIDOSHA KABUSHIKI KAISHA, Toyota-shi (JP)

(21) Appl. No.: 19/439,722

(22) Filed: Jan. 5, 2026

(30) Foreign Application Priority Data
Jan. 9, 2025 (JP) 2025-003270

(51) Int. Cl. G01R 31/389; G01R 31/378; G01R 31/396; G01R 35/00; H01M 10/0525

(52) U.S. Cl. CPC G01R 31/389; G01R 31/378; G01R 31/396; G01R 35/005; H01M 10/0525

(57) ABSTRACT

A calibration method of a battery electronic control unit (ECU) according to the present disclosure uses an inspection device. The battery ECU includes a first high-frequency signal supplying unit that supplies a first high-frequency signal of 0.1 MHz or higher to a lithium-ion secondary battery, and a first detecting unit that detects a value of a real part of alternating current impedance from the lithium-ion secondary battery where the first high-frequency signal has been supplied. The inspection device can detect the value of the real part of the alternating current impedance from the lithium-ion secondary battery with higher precision than the battery ECU. In the calibration method of the battery ECU, in a shipping inspection process of the lithium-ion secondary battery, an ECU impedance measurement value is acquired by detecting the value of the real part of the alternating current impedance of the lithium-ion secondary battery, using the battery ECU.

### CROSS-REFERENCE TO RELATED APPLICATION

This application claims priority to Japanese Patent Application No. 2025-003270 filed on Jan. 9, 2025. The disclosure of the above-identified application, including the specification, drawings, and claims, is incorporated by reference herein in its entirety.

### BACKGROUND

### 1. Technical Field

The present disclosure relates to a calibration method of a battery electronic control unit (ECU).

### 2. Description of Related Art

There is a demand to suppress deposition of metallic lithium (Li) (hereinafter referred to as “Li deposition”) in lithium-ion secondary batteries, in order to suppress deterioration in performance of the lithium-ion secondary batteries. However, no non-destructive method was known to detect Li deposition in lithium-ion secondary batteries.

To address this issue, the present inventors developed a technique for detecting a real part of alternating current impedance of a lithium-ion secondary battery using high-frequency signals, and calculating an amount of Li deposition in the lithium-ion secondary battery based on a difference between a current value and an initial value of the real part of the alternating current impedance, as disclosed in Japanese Patent No. 7347451 (JP 7347451 B).

### SUMMARY

Now, lithium-ion secondary batteries include components such as built-in sensors, wire harnesses, and so forth. There has been concern that variance among such components might reduce precision of impedance measurement.

The present disclosure has been made in light of the above problem, and provides a calibration method of a battery ECU that can suppress risk of reduction in precision of impedance measurement.

A calibration method for calibrating a battery ECU according to the present disclosure
is a calibration method for calibrating the battery ECU using an inspection device, in which
the battery ECU includes a first high-frequency signal supplying unit that supplies a first high-frequency signal of 0.1 MHz or higher to a lithium-ion secondary battery, and a first detecting unit that detects a value of a real part of alternating current impedance from the lithium-ion secondary battery to which the first high-frequency signal has been supplied, and
the inspection device detects the value of the real part of the alternating current impedance from the lithium-ion secondary battery with higher precision than the battery ECU, the calibration method including
acquiring an ECU impedance measurement value, in a shipping inspection process of the lithium-ion secondary battery, using the battery ECU to detect the value of the real part of the alternating current impedance of the lithium-ion secondary battery,
acquiring an inspection device impedance measurement value, using the inspection device to detect the value of the real part of the alternating current impedance of the lithium-ion secondary battery,
notifying the battery ECU of the inspection device impedance measurement value, and
calibrating the first detecting unit using a difference between the ECU impedance measurement value and the inspection device impedance measurement value, as a calibration value.

In the above-described calibration method, the first high-frequency signal supplying unit may supply the first high-frequency signal of 0.5 MHz or higher to the lithium-ion secondary battery.

In the above-described calibration method, the lithium-ion secondary battery may include a plurality of battery cells, and the calibration method may further include
acquiring the ECU impedance measurement value using the battery ECU, in the shipping inspection process for the lithium-ion secondary battery, by the first high-frequency signal supplying unit supplying the first high-frequency signal to at least one battery cell among the battery cells, and the first detecting unit detecting the value of the real part of the alternating current impedance of the at least one battery cell, and
acquiring the inspection device impedance measurement value using the inspection device, by detecting the value of the real part of the alternating current impedance of the at least one battery cell.

In the above-described calibration method, the lithium-ion secondary battery may include a plurality of battery cells, and the calibration method may further include
acquiring the inspection device impedance measurement value using the inspection device, in the shipping inspection process for the lithium-ion secondary battery, by acquiring the ECU impedance measurement value using the battery ECU, through applying electricity to the battery cells such that a voltage value of the battery cells is within a predetermined range.

The above-described calibration method may further include acquiring the ECU impedance measurement value, in the shipping inspection process for the lithium-ion secondary battery, by supplying an alternating current signal, that is a test signal generated by a three-phase inverter, to the lithium-ion secondary battery in accordance with a particular switching pattern for supplying to the lithium-ion secondary battery, while using the battery ECU to detect the value of the real part of the alternating current impedance of the lithium-ion secondary battery.

According to the present disclosure, the risk of decrease in impedance measurement precision can be suppressed.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating a configuration example of a battery calibration system according to a first embodiment;

FIG. 2 is a diagram showing a relation between a state of health (SOH) of a secondary battery and an amount of change in a real part Z of alternating current impedance when a high-frequency signal of 1 MHz is supplied to the secondary battery;

FIG. 3 is a diagram showing a relation between frequency of an alternating current signal supplied to the secondary battery and the real part of the alternating current impedance detected from the secondary battery;

FIG. 4 is a diagram showing the relation between the frequency of the alternating current signal supplied to the secondary battery and the real part of the alternating current impedance detected from the secondary battery;

FIG. 5 is a diagram illustrating a specific configuration example of an impedance detecting unit provided in the battery calibration system according to the first embodiment;

FIG. 6 is a diagram showing attenuation characteristics of a high-frequency signal supplied from a high-frequency signal supplying unit to a secondary battery when calculating an amount of Li deposition;

FIG. 7 is a timing chart for describing detection error of peak voltage Vo due to variance among components of the secondary battery; and

FIG. 8 is a flowchart showing a calibration method for a battery electronic control unit (ECU) according to the first embodiment.

### DETAILED DESCRIPTION OF EMBODIMENTS

Specific embodiments to which the present disclosure is applied will be described in detail below with reference to the drawings. Note, however, that the present disclosure is not limited to the following embodiments. The following description and drawings are simplified as appropriate for clarity of description.

### First Embodiment

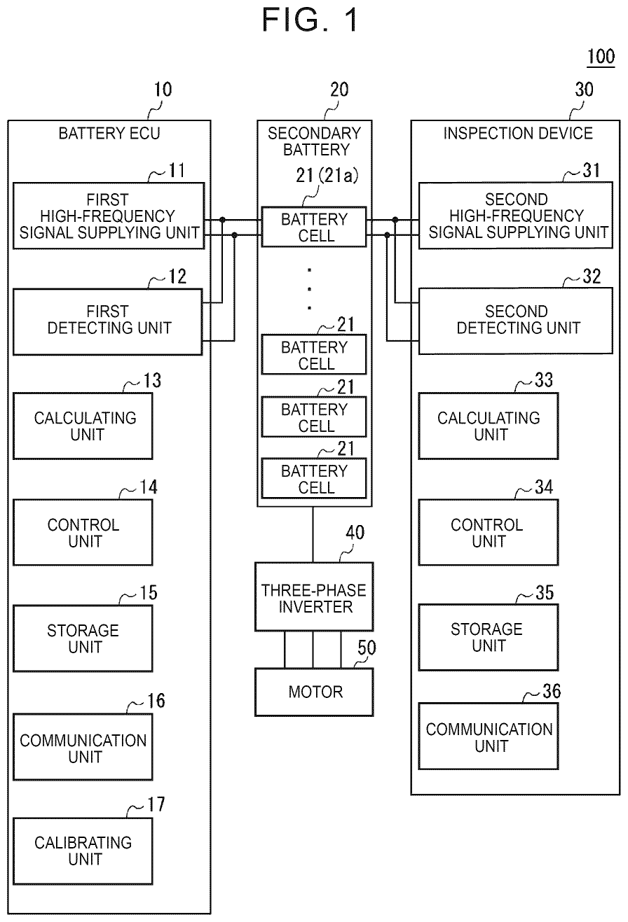

FIG. 1 is a block diagram illustrating a configuration example of a battery calibration system according to a first embodiment. As illustrated in FIG. 1, a battery calibration system 100 includes a battery electronic control unit (ECU) 10, a secondary battery 20, and an inspection device 30. The battery ECU 10 manages the secondary battery 20. The battery ECU 10 and the secondary battery 20 can be installed in a vehicle that is omitted from illustration. The inspection device 30 inspects the secondary battery 20 as the object thereof, and is preferably provided so as to be detachable from the secondary battery 20. The battery calibration system 100 further includes a three-phase inverter 40 that is driven by power from the secondary battery 20. FIG. 1 also illustrates a motor 50 that is driven by the three-phase inverter 40. The three-phase inverter 40 can supply alternating current or signals to the secondary battery 20.

### Configuration of Secondary Battery 20

First, the secondary battery 20 will be described.

The secondary battery 20 is a lithium-ion secondary battery, and is made up of a cell stack made up of a plurality of battery cells 21 that is stacked, and a case that accommodates the cell stack. Each of the battery cells includes a cathode, an anode, and an ionic transmission medium that is provided between the cathode and the anode, and that conducts carrier ions. A separator may further be provided between the cathode and the anode. A resin such as polyethylene, polypropylene, or the like is used for the separator. The secondary battery 20 also includes components such as a built-in sensor, a wire harness, and so forth.

A cathode active material is, for example, a sulfide containing a transition metal element, an oxide containing lithium and a transition metal element, or the like. Specifically, the cathode active material uses a lithium manganese composite oxide with a basic composition formula such as Li₍₁₋ₓ₎MnO₂ (where 0<x<1), Li₍₁₋ₓ₎Mn₂O₄ or the like, a lithium cobalt composite oxide with a basic composition formula such as Li₍₁₋ₓ₎CoO₂ or the like, a lithium nickel composite oxide with a basic composition formula such as Li₍₁₋ₓ₎NiO₂ or the like, a lithium nickel cobalt manganese composite oxide with a basic composition formula such as Li₍₁₋ₓ₎NiₐCo_{b}Mn_{c}O₂ (where a+b+c=1) or the like, and so forth. Note that a substance with the above basic composition formula containing other elements may be used for the cathode active material. Aluminum (Al) or the like, for example, is used for a current collector of the cathode.

A composite oxide containing lithium, a carbon material, or the like, for example is used for an anode active material. Specifically, an inorganic compound such as lithium, a lithium alloy, a tin compound, or the like, a carbon material that is capable of intercalating and deintercalating lithium ions, a composite oxide containing a plurality of elements, a conductive polymer, or the like, is used for the anode active material. Examples of the carbon material to be used for the anode active material include cokes, glassy carbons, graphites, non-graphitizable carbons, pyrolytic carbons, carbon fibers, and so forth, of which graphites such as artificial graphite, natural graphite, and so forth, are preferable. Also, examples of the composite oxide to be used for the anode active material include lithium titanium composite oxides, lithium vanadium composite oxides, and so forth. Copper (Cu) or the like, for example, is used for a current collector of the anode.

An ionically conductive medium is used as an electrolytic solution, for example, by dissolving a supporting salt. A lithium salt such as LiPF₆, LiBF₄, or the like, for example, is used for the supporting salt. Any one of carbonates, esters, ethers, nitriles, furans, sulfolanes, and dioxolanes, or a mixture of several of these, for example, is used as a solvent for the electrolytic solution. Examples of the carbonates include cyclic carbonates such as ethylene carbonate, propylene carbonate, vinylene carbonate, butylene carbonate, chloroethylene carbonate, and so forth, and linear carbonates such as dimethyl carbonate, ethyl methyl carbonate, diethyl carbonate, ethyl-n-butyl carbonate, methyl-t-butyl carbonate, di-i-propyl carbonate, t-butyl-i-propyl carbonate, and so forth. Alternatively, a solid ionically conductive polymer, an inorganic solid electrolyte, a mixed material of an organic polymer electrolyte and an inorganic solid electrolyte, an inorganic solid powder that is bound by an organic binder, or the like, may be used for the ionically conductive medium.

Now, in the secondary battery 20, metallic Li is deposited on electrode surfaces of each of the battery cells 21 as a result of repeated charging. Li deposition advances more as the charging power is increased to increase the charging rate, and causes deterioration of the state of health (SOH) of the secondary battery 20.

Note that the SOH of the secondary battery 20 refers to the percentage of the current fully charged capacity of the secondary battery 20 when the initial fully charged capacity is 100%.

### Configuration of Battery ECU 10

Next, the battery ECU 10 that manages the secondary battery 20 will be described.

As illustrated in FIG. 1, the battery ECU 10 includes a first high-frequency signal supplying unit 11, a first detecting unit 12, a calculating unit 13, a control unit 14, a storage unit 15, a communication unit 16, and a calibrating unit 17, and manages the charging and discharging of the secondary battery 20 that is to be managed. The battery ECU 10 calculates amount of Li deposited in the secondary battery 20.

The battery ECU 10 includes, as hardware, a computing unit that is omitted from illustration such as a central processing unit (CPU) or the like, in addition to the storage unit 15 such as random access memory (RAM), read-only memory (ROM), or the like, storing various types of programs and data and so forth. That is to say, the battery ECU 10 functions as a computer, and performs various types of processing based on the aforementioned various types of programs and the like.

Accordingly, the functional blocks of the first high-frequency signal supplying unit 11, the first detecting unit 12, the calculating unit 13, the control unit 14, the storage unit 15, and the communication unit 16 that make up the battery ECU 10 in FIG. 1 can be configured in terms of hardware using a CPU, memory, and other circuits, and can be realized in terms of software using a program loaded to memory, or the like. That is to say, each of the functional blocks above can be realized in various forms using computer hardware, software, or a combination thereof.

The first high-frequency signal supplying unit 11 supplies high-frequency signals, for detecting the amount of Li deposition, to the secondary battery 20. Specifically, the first high-frequency signal supplying unit 11 supplies a first high-frequency signal of 0.1 MHz or higher to battery cells 21 of the secondary battery 20. More specifically, the first high-frequency signal supplying unit 11 supplies the first high-frequency signal of 0.1 MHz or higher to a battery cell 21a. The first high-frequency signal preferably is a high-frequency signal such that the value of the real part of the alternating current impedance detected is 10 times or more greater, due to the skin effect, as compared to a value of a real part Z of the alternating current impedance detected when an alternating current signal of 1 kHz is supplied to the secondary battery 20. Specifically, the frequency of the first high-frequency signal is preferably 0.5 MHz or higher.

When the first high-frequency signal is supplied to the secondary battery 20, diffusion, reaction, and movement of lithium ions cannot keep up in each of the battery cells 21 of the secondary battery 20. Accordingly, current of the first high-frequency signal flows, due to the skin effect, over the electrode surfaces of each of the battery cells 21 where Li deposition readily occurs.

The smaller the amount of Li deposition is, the lower the electrical conductivity of the electrode surface of each of the battery cells 21 is, and therefore the greater the value of the real part Z of the alternating current impedance is. On the other hand, the greater the amount of Li deposition is, the higher the electrical conductivity of the electrode surfaces of each of the battery cells 21 is, and accordingly, the value of the real part Z of the alternating current impedance becomes smaller. Now, a great amount of current is concentrated on the Li metal having high electrical conductivity, and accordingly, magnetic fields change around Li deposition regions, and eddy currents are generated in accordance therewith. Such eddy currents cause loss in conductive portions of current collecting foils and electrodes, but reduce loss in the battery as a whole. Accordingly, the greater the amount of Li deposition is, the greater the change in the magnetic field is, and the eddy currents become greater in accordance therewith, and accordingly the value of the real part Z decreases. Thus, the amount of Li deposition in the secondary battery 20 can be calculated from amount of change in the real part Z of the alternating current impedance (difference between the detected value and the initial value) detected from the secondary battery 20 supplied with the first high-frequency signal. Further, the SOH of the secondary battery 20 can also be estimated based on the amount of Li deposition.

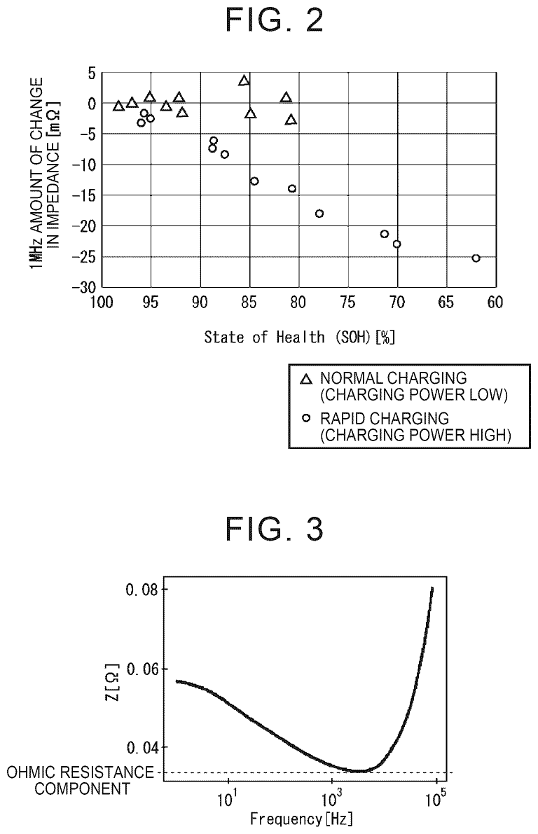

Now, FIG. 2 is a graph showing a relation between the SOH of the secondary battery 20, and the amount of change in the real part Z of the alternating current impedance (difference between the detected value and the initial value) when the high-frequency signal of 1 MHz is supplied to the secondary battery 20.

As indicated by triangle marks in FIG. 2, in the case of normal charging with small charging power, the amount of Li deposition is small even when charging is repeated, and accordingly the amount of change in the real part Z of the alternating current impedance remains small even when deterioration of the SOH advances due to some other factor. That is to say, the detected value of the real part Z of the alternating current impedance is maintained at a high value.

On the other hand, as indicated by circle marks in FIG. 2, in the case of rapid charging with a great charging power, the amount of Li deposition increases with repeated charging, and accordingly, the deterioration of the SOH advances in accordance therewith, and the amount of change in the real part Z of the alternating current impedance becomes great. That is to say, the detected value of the real part Z of the alternating current impedance is low. Note that when Li deposition is a predominant battery degradation cause among causes of the battery degradation, the amount of Li deposition can be derived from the SOH. Alternatively, the SOH can be derived from the amount of Li deposition.

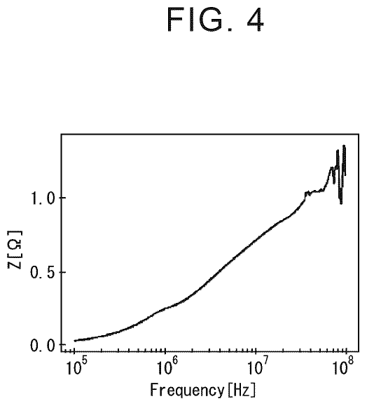

FIGS. 3 and 4 are graphs showing a relation between the frequency of the alternating current signal supplied to the secondary battery 20 and the real part of the alternating current impedance detected from the secondary battery 20. FIG. 3 shows the value of the real part Z of the alternating current impedance when alternating current signals ranging from 1 kHz to 100 kHz are supplied to the secondary battery 20. FIG. 4 shows the value of the real part Z of the alternating current impedance when alternating current signals ranging from 100 kHz to 100 MHz are supplied to the secondary battery 20.

As shown in FIG. 3, when an alternating current signal of around 1 kHz is supplied to the secondary battery 20, the value of the real part Z of the alternating current impedance is a minimum value. This impedance component represents an ohmic resistance component. As also shown in FIGS. 3 and 4, as the frequency of the alternating current signal supplied to the secondary battery 20 increases, the skin effect causes the current flow to concentrate on the electrode surface of each of the cells, and accordingly the value of the real part Z of the alternating current impedance increases.

Accordingly, the first high-frequency signal supplying unit 11 supplies the secondary battery 20 with an alternating current signal (i.e., first high-frequency signal) having such a high frequency that the value of the real part Z of the alternating current impedance, which is sufficiently high as compared to the ohmic resistance component, can be detected.

The first detecting unit 12 detects an ECU impedance measurement value Ze from the secondary battery 20 to which the first high-frequency signal is supplied. The ECU impedance measurement value Ze is the value of the real part Z of the alternating current impedance. As described above, the current of the first high-frequency signal supplied from the first high-frequency signal supplying unit 11 to the secondary battery 20 flows over the electrode surface (Li deposition region) of each of the battery cells 21 of the secondary battery 20, due to the skin effect. Also, even when the Li metal is electrically disconnected from the anode after Li deposition and is in a floating state, the current still flows over the Li metal due to inductive coupling and capacitive coupling. Accordingly, the first detecting unit 12 can detect the real part Z of the alternating current impedance in accordance with the amount of deposited Li.

The calculating unit 13 calculates the amount of Li deposition in the secondary battery 20 based on the difference between the current value of the real part Z of the alternating current impedance detected by the first detecting unit 12 and the initial value of the real part Z of the alternating current impedance of the secondary battery 20. Specifically, the greater the detected value of the real part Z of the alternating current impedance is, and the smaller the difference between the detected value and the initial value is, the smaller the value of the amount of Li deposition that the calculating unit 13 calculates is. Conversely, the smaller the detected value of the real part Z of the alternating current impedance is, and the greater the difference between the detected value and the initial value is, the greater the value of the amount of Li deposition that the calculating unit 13 calculates is.

Note that an initial value of the real part Z of the alternating current impedance of the secondary battery 20 is stored in the storage unit 15, for example. Also, the storage unit 15 may store map information that represents a relation between a difference (amount of change) between the current value (detected value) and the initial value of the real part Z of the alternating current impedance of each type of secondary battery, and the amount of Li deposition. It is preferable for the storage unit 15 to store the ECU impedance measurement value Ze.

This map information is information that is obtained in advance, for example, through experimentation or the like, but may also be updated as appropriate using information detected from the secondary battery 20, such as for example, the ECU impedance measurement value Ze and an inspection device impedance measurement value Zi described below. When using the map information, the calculating unit 13 extracts the amount of Li deposition, corresponding to the value of the real part Z of the alternating current impedance detected by the first detecting unit 12, from the map information stored in the storage unit 15.

The communication unit 16 acquires the inspection device impedance measurement value Zi from a communication unit 36 (described later) of the inspection device 30, via an in-vehicle network. The storage unit 15 may store the inspection device impedance measurement value Zi.

The calibrating unit 17 calibrates the first detecting unit 12 using the difference between the ECU impedance measurement value Ze and the inspection device impedance measurement value Zi as a calibration value.

### Configuration of Inspection Device 30

Next, the inspection device 30 will be described.

As illustrated in FIG. 1, the inspection device 30 includes a second high-frequency signal supplying unit 31, a second detecting unit 32, a calculating unit 33, a control unit 34, a storage unit 35, and a communication unit 36. The inspection device 30 can detect the value of the real part Z of the alternating current impedance from the secondary battery 20 with higher precision as compared to the battery ECU 10.

Here, the inspection device 30 includes, as hardware, a computing unit that is omitted from illustration such as a CPU or the like, in addition to the storage unit 35 such as RAM, ROM, or the like, storing various types of programs and data and so forth. That is to say, the inspection device 30 functions as a computer, and performs various types of processing based on the aforementioned various types of programs and the like.

Accordingly, the functional blocks of the second high-frequency signal supplying unit 31, the second detecting unit 32, the control unit 34, the storage unit 35, and the communication unit 36 that make up the inspection device 30 in FIG. 1 can be configured in terms of hardware using a CPU, memory, and other circuits, and can be realized in terms of software using a program loaded to memory, or the like. That is to say, each of the functional blocks above can be realized in various forms using computer hardware, software, or a combination thereof.

The second high-frequency signal supplying unit 31 supplies the secondary battery 20 with a high-frequency signal for detecting the amount of deposited Li, similar to the first high-frequency signal supplying unit 11. Specifically, the second high-frequency signal supplying unit 31 supplies a second high-frequency signal of 0.1 MHz or higher to the battery cells 21 of the secondary battery 20. More specifically, the second high-frequency signal supplying unit 31 supplies a second high-frequency signal of 0.1 MHz or higher to the battery cell 21a. The second high-frequency signal preferably is a high-frequency signal such that the value of the real part of the alternating current impedance that is detected is 10 times or more greater, due to the skin effect, as compared to the value of the real part Z of the alternating current impedance that is detected when an alternating current signal of 1 kHz is supplied to the secondary battery 20. Specifically, the frequency of the second high-frequency signal is preferably 0.5 MHz or higher. Also, the second high-frequency signal supplying unit 31 preferably supplies the second high-frequency signal in accordance with a particular switching pattern.

The second detecting unit 32 detects the value of the real part Z of the alternating current impedance from the secondary battery 20, to which the second high-frequency signal is supplied, with higher precision than the first detecting unit 12. The second detecting unit 32 may have the same configuration as the first detecting unit 12, except for the detection precision of the value of the real part Z of the alternating current impedance. The current of the second high-frequency signal is similar to the current of the first high-frequency signal described above. That is to say, the current of the second high-frequency signal flows over the electrode surface (Li deposition region) of each of the battery cells 21 of the secondary battery 20, due to the skin effect. Also, even when the Li metal is electrically disconnected from the anode after Li deposition and is in a floating state, the current still flows over the Li metal due to inductive coupling and capacitive coupling. Accordingly, the second detecting unit 32 can detect the real part Z of the alternating current impedance according to the amount of deposited Li.

The storage unit 35 may store the initial value of the real part Z of the alternating current impedance of the secondary battery 20 and the map information described above, similar to the storage unit 15. The calculating unit 33 may calculate the amount of deposited Li from the real part Z of the alternating current impedance detected by the second detecting unit 32, similar to the calculating unit 13.

The control unit 34 transmits the inspection device impedance measurement value Zi to the communication unit 16 of the battery ECU 10 via the in-vehicle network, using the communication unit 36. The inspection device impedance measurement value Zi includes, for example, the real part Z of the alternating current impedance detected by the second detecting unit 32.

Now, error may be included in the detected value of the real part Z of the alternating current impedance that is detected by the first detecting unit 12, due to effects of variance and so forth in components of the secondary battery 20. Accordingly, in the battery ECU 10 according to the present embodiment, the detected error is calibrated by the calibrating unit 17 during, for example, a shipping inspection process. As a result, the battery ECU 10 according to the present embodiment can reduce the risk of the impedance measurement precision of the secondary battery 20 decreasing.

In the following, first, a specific configuration example of the first detecting unit 12 will be described, and then error that can occur in the first detecting unit 12, and calibration thereof by the calibrating unit 17, will be described.

### Specific Configuration Example of First Detecting Unit 12

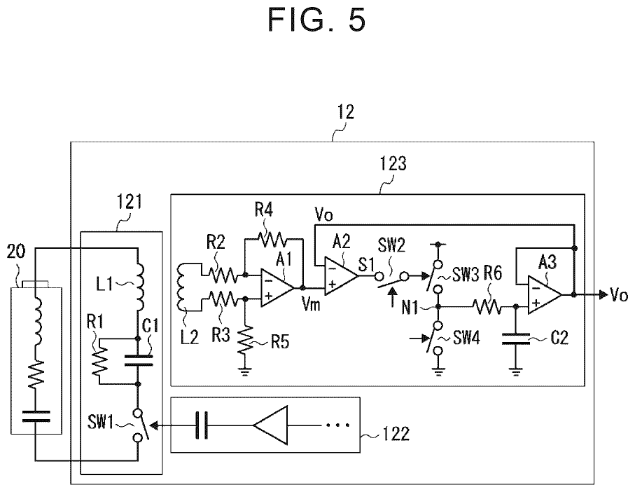

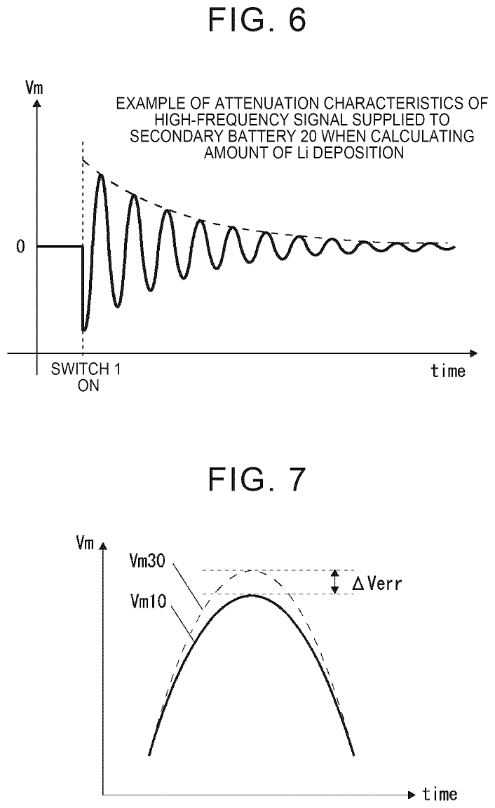

FIG. 5 is a diagram illustrating a specific configuration example of the first detecting unit 12 provided in the battery ECU 10. The secondary battery 20 is also illustrated in FIG. 5. FIG. 6 is a diagram showing attenuation characteristics of the first high-frequency signal supplied from the first high-frequency signal supplying unit 11 to the secondary battery 20 when calculating the amount of deposited Li. Note that the second detecting unit 32 may have the same configuration as the specific example of the configuration of the first detecting unit 12 illustrated in FIG. 5, except for the detection precision.

As illustrated in FIG. 5, the first detecting unit 12 includes a resonance circuit 121, a trigger signal output circuit 122, and a peak holding circuit 123. The first detecting unit 12 is also referred to as an impedance detecting circuit. The resonance circuit 121 corresponds to the first high-frequency signal supplying unit 11.

The resonance circuit 121 is a circuit that resonates at a high frequency (frequency of high-frequency signal from first high-frequency signal supplying unit 11).

Specifically, the resonance circuit 121 includes an inductor L1, a capacitor C1, a resistive element R1, and a switch SW1. The resistive element R1 is provided in parallel with the capacitor C1. The inductor L1, the capacitor C1, and the switch SW1 are provided being connected in series between the cathode and the anode of the secondary battery 20. The trigger signal output circuit 122 activates a trigger signal based on an instruction from the control unit 14, for example, thereby temporarily turning on the switch SW1. When the switch SW1 is turned on, the resonance circuit 121 starts resonating at a high frequency.

The peak holding circuit 123 detects the value of the real part Z of the alternating current impedance of the secondary battery 20, from the attenuation characteristics of the high-frequency signal supplied to the secondary battery 20.

Specifically, the peak holding circuit 123 includes an inductor L2, resistive elements R2 to R6, amplifiers A1 to A3, and switches SW2 to SW4. The inductor L2 is magnetically coupled to the inductor L1 and receives the high-frequency signal flowing through the inductor L1. The resistive element R2 is provided between one end of the inductor L2 and an inverting input terminal of the amplifier A1. The resistive element R3 is provided between another end of the inductor L2 and a non-inverting input terminal of the amplifier A1. The resistive element R4 is provided between an output terminal and the inverting input terminal of the amplifier A1. The resistive element R5 is provided between the non-inverting input terminal of the amplifier A1 and the ground. The amplifier A1 amplifies the high-frequency signal received by the inductor L2 from the inductor L1 and outputs the amplified signal as an output voltage Vm.

The amplifier (hereinafter, comparator) A2 compares the output voltage Vm of the amplifier A1 (amplified voltage of high-frequency signal) with output voltage Vo of the amplifier A3 (output voltage of peak holding circuit 123), and outputs a comparison result S1. When the output voltage Vm of the amplifier A1 is lower than the output voltage Vo of the amplifier A3, for example, the comparator A2 outputs an L-level comparison result S1, and when the output voltage Vm of the amplifier A1 is equal to or greater than the output voltage Vo of the amplifier A3, outputs an H-level comparison result S1.

The switch SW2 is provided between an output terminal of the amplifier A2 and a control terminal of the switch SW3, and is controlled to be turned off during initialization and to be turned on otherwise. Note, however, when signals of a plurality of different frequencies are input for different periods, and acquiring just an amplitude of a signal of a certain particular frequency is desired, the switch SW2 may be controlled to be on only during the period in which the signal of that particular frequency is input, and may be turned off otherwise.

The switch SW3 is provided between a power supply voltage terminal to which a power supply voltage is supplied, and a node N1. The switch SW4 is provided between the node N1 and the ground. The resistive element R6 is provided between the node N1 and a non-inverting input terminal of the amplifier A3. An output terminal and an inverting input terminal of the amplifier A3 are connected to each other. A capacitor C2 is provided between the non-inverting input terminal of the amplifier A3 and the ground. The switch SW3 is turned off when the L-level comparison result S1 of the amplifier A2 is supplied via the switch SW2, and is turned on when the H-level comparison result S1 of the amplifier A2 is supplied via the switch SW2. The switch SW4 is controlled to be turned on when the charge stored in the capacitor C2 is to be released to the ground during initialization, and is otherwise turned off.

For example, when the output voltage Vm of the amplifier A1 is lower than the output voltage Vo of the amplifier A3, the switch SW3 remains off, and accordingly no additional charge is stored in the capacitor C2. Thus, the amplifier A3 maintains the output voltage Vo at the current value. On the other hand, when the output voltage Vm of the amplifier A1 is equal to or higher than the output voltage Vo of the amplifier A3, the switch SW3 turns on, and accordingly additional charge is stored in the capacitor C2 for the period during which the switch SW3 is on. This causes the amplifier A3 to increase the output voltage Vo by a value corresponding to the increase in the charge. Repeating this processing causes the output voltage Vo to gradually approach the peak voltage of the high-frequency signal, and finally reach the peak voltage of the high-frequency signal or a voltage equivalent thereto. Thus, the peak holding circuit 123 detects the peak voltage (Vo) of the high-frequency signal.

Note that the peak holding circuit 123 detects the attenuation characteristics of the high-frequency signal based on peak voltages of the high-frequency signal at two or more points, and detection intervals of these peak voltages. That is to say, the peak holding circuit 123 detects the attenuation characteristics of the high-frequency signal from the amount of change in the peak voltage Vo per unit time. Note that calculation of the attenuation characteristics of the high-frequency signal may be performed in the calculating unit 13.

### Detection Error of Peak Voltage Vo Due to Variance Among Components of Secondary Battery 20

FIG. 7 is a timing chart for describing detection error of the peak voltage Vo caused by variance among the components of the secondary battery 20. Note that FIG. 7 shows one of signal waveforms that is convex in a positive direction, from among the high-frequency signals represented by the voltage Vm.

As shown in FIG. 7, variance among the components of the secondary battery 20 can cause the peak of the voltage Vm to fluctuate. In the example of FIG. 7, voltage Vm10 detected by the battery ECU 10 includes an error of a voltage ΔVerr as compared to voltage Vm30 detected by the inspection device 30. The voltage Vm includes the error voltage ΔVerr, and accordingly the voltage Vo also includes the error voltage ΔVerr, as a matter of course.

Accordingly, the calibrating unit 17 corrects the output voltage Vo of the peak holding circuit 123 so as to cancel out the error voltage ΔVerr. Thus, the calibrating unit 17 extracts the error voltage ΔVerr from the storage unit 15 and performs adding thereof to the output voltage Vo of the peak holding circuit 123. This suppresses detection error in the peak voltage Vo due to variance among the components of the secondary battery 20.

A different error voltage ΔVerr, for each type of secondary battery 20, or for each individual product, may be stored in the storage unit 15. A method for acquiring the error voltage ΔVerr stored in the storage unit 15 will be described below.

First, in a test mode, from among operation modes that include a normal operation mode and the test mode, the control unit 34 of the inspection device 30 causes the three-phase inverter 40 to generate an alternating current signal that is a test signal having an amplitude and cycle (pulse width) in accordance with test contents. This test signal is an alternating current signal having a frequency approximately equal to that of the high-frequency signal generated by the first high-frequency signal supplying unit 11. This test signal generated by the three-phase inverter 40 is supplied to the secondary battery 20. Also, the control unit 14 controls the switch SW1 to on.

Thereafter, the calculating unit 13 extracts the difference (e.g., error voltage ΔVerr) between the peak voltage Vo of the test signal detected by the first detecting unit 12 and the peak voltage Vo of the test signal detected by the second detecting unit 32. Information regarding the error voltage ΔVerr that is extracted is stored in the storage unit 15.

Note that the peak voltage Vo of the test signal detected by the second detecting unit 32 is more highly precise than the peak voltage Vo of the test signal detected by the first detecting unit 12.

The control unit 34 causes the three-phase inverter 40 to supply a plurality of test signals having various types of cycles and amplitudes to the secondary battery 20. The calculating unit 13 extracts the difference (e.g., error voltage ΔVerr) between the peak voltage Vo of each of the test signals detected by the first detecting unit 12 and the peak voltage Vo of the corresponding test signal detected by the second detecting unit 32, and performs storage thereof in the storage unit 15. Thus, the storage unit 15 stores a plurality of combinations of second high-frequency signals with different waveform patterns, and the error voltages ΔVerr corresponding thereto.

This enables the battery ECU 10 to correct the detection error of the second detecting unit 32 with high precision, even when the amplitude and the cycle of the high-frequency signal are different. As a result, the amount of Li deposited in the secondary battery 20 can be detected with high precision.

### Calibration Method

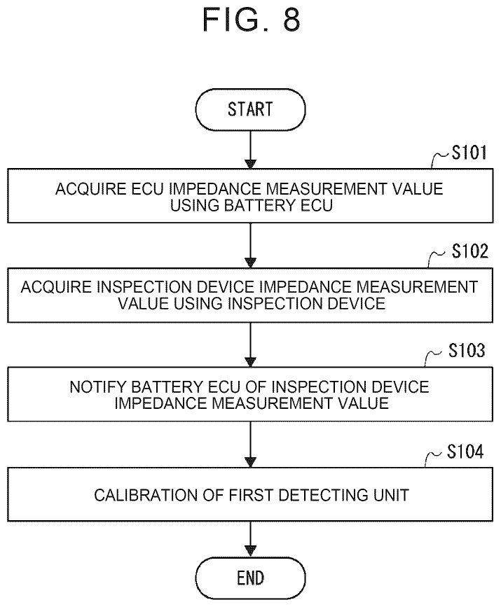

Next, a calibration method according to the present embodiment, i.e., operations of the battery calibration system 100, will be described with reference to FIG. 8. FIG. 8 is a flowchart showing the calibration method according to the first embodiment. The calibration method according to the present embodiment can be used in the shipping inspection process of the secondary battery 20.

First, the battery calibration system 100 detects the value of the real part of the alternating current impedance of the secondary battery 20, using the battery ECU 10 to acquire the ECU impedance measurement value Ze (step S101). The first high-frequency signal supplying unit 11 may supply a first high-frequency signal to at least one battery cell 21 among the battery cells 21, and the first detecting unit 12 may detect the value of the real part of the alternating current impedance of the at least one battery cell 21. Specifically, the first high-frequency signal supplying unit 11 supplies a first high-frequency signal to the battery cell 21a, and the first detecting unit 12 detects the value of the real part of the alternating current impedance of the secondary battery 20 from the battery cell 21a. The control unit 14 stores the value of the real part of the alternating current impedance of this secondary battery 20 that is detected, in the storage unit 15, as the ECU impedance measurement value Ze.

Next, the battery calibration system 100 detects the value of the real part of the alternating current impedance of the secondary battery 20, using the inspection device 30, to acquire the inspection device impedance measurement value Zi (step S102). The second detecting unit 32 may detect the value of the real part of the alternating current impedance of at least one battery cell 21. The second detecting unit 32 preferably detects the value of the real part of the alternating current impedance of the battery cell 21 detected by the first detecting unit 12 in step S101. In other words, the battery cell 21 detected by the first detecting unit 12 in step S101 and the battery cell 21 detected by the second detecting unit 32 in this step S102 is preferably the same. Specifically, the second high-frequency signal supplying unit 31 supplies a second high-frequency signal to the battery cell 21a, and the second detecting unit 32 detects the value of the real part of the alternating current impedance of the secondary battery 20 from the battery cell 21a. The control unit 34 stores the value of the real part of the alternating current impedance of the secondary battery 20 that is detected, in the storage unit 35, as the inspection device impedance measurement value Zi. Also, the three-phase inverter 40 may supply a second high-frequency signal having the same frequency as the first high-frequency signal supplied in step S101. Further, the three-phase inverter 40 preferably supplies test signals in accordance with a particular switching pattern. In step S102, the three-phase inverter 40 may supply alternating current to the battery cell 21a of the secondary battery 20.

Next, the battery calibration system 100 notifies the battery ECU 10 of the inspection device impedance measurement value Zi (step S103). Specifically, the control unit 34 of the inspection device 30 instructs the communication unit 36, and the communication unit 36 transmits the inspection device impedance measurement value Zi to the communication unit 16 of the battery ECU 10. The control unit 14 stores the inspection device impedance measurement value Zi acquired by the communication unit 16 in the storage unit 35.

Finally, the battery calibration system 100 calibrates the first detecting unit 12 using the difference between the ECU impedance measurement value Ze and the inspection device impedance measurement value Zi as a calibration value (step S104). Specifically, the calculating unit 13 increases or decreases the value of the real part of the alternating current impedance detected by the first detecting unit 12, so as to resolve the difference between the ECU impedance measurement value Ze and the inspection device impedance measurement value Zi. As described above, the inspection device 30 detects the value of the real part of the alternating current impedance from the secondary battery 20 with higher precision than the battery ECU 10. Thus, the calculating unit 13 can calculate the amount of deposited Li with high precision, using the value of the real part of the alternating current impedance that is detected with high precision.

In this way, the battery ECU 10 can be calibrated by the battery ECU 10 acquiring the calibration value of the first detecting unit 12. This can suppress the risk of the impedance measurement precision decreasing due to variance among components of the secondary battery 20, such as built-in sensors and wire harnesses, for example.

Also, the battery cell 21a detected by the first detecting unit 12 in step S101 is the same as the battery cell 21a detected by the second detecting unit 32 in this step S102. This enables the battery ECU 10 and the inspection device 30 to acquire impedance measurement values from the same battery cell 21a.

Also, in step S101, the three-phase inverter 40 applies electricity to the battery cells 21 such that the voltage values of the battery cells 21 are within a predetermined range, whereby the ECU impedance measurement value Ze is acquired using the battery ECU 10. Also, in step S102, the inspection device 30 is used to acquire the inspection device impedance measurement value Zi. This enables effects of the voltage value of the battery cell 21 on the impedance to be suppressed.

Also, in step S102, the three-phase inverter 40 supplies test signals to the secondary battery 20 in accordance with a particular switching pattern. Accordingly, impedance measurement values in accordance with various switching patterns can be acquired, and highly precise calibration values for the second detecting unit 32 can be acquired.

Note that the present disclosure is not limited to the above embodiments, and can be modified as appropriate without departing from the spirit and scope thereof. Also, the present disclosure may be carried out by combining the above embodiments and examples thereof as appropriate.

What is claimed is:

1. A calibration method for calibrating a battery electronic control unit (ECU) using an inspection device, wherein
the battery ECU includes a first high-frequency signal supplying unit that supplies a first high-frequency signal of 0.1 MHz or higher to a lithium-ion secondary battery, and a first detecting unit that detects a value of a real part of alternating current impedance from the lithium-ion secondary battery to which the first high-frequency signal has been supplied, and
the inspection device detects the value of the real part of the alternating current impedance from the lithium-ion secondary battery with higher precision than the battery ECU, the calibration method comprising:
acquiring an ECU impedance measurement value, in a shipping inspection process of the lithium-ion secondary battery, using the battery ECU to detect the value of the real part of the alternating current impedance of the lithium-ion secondary battery;
acquiring an inspection device impedance measurement value, using the inspection device to detect the value of the real part of the alternating current impedance of the lithium-ion secondary battery;
notifying the battery ECU of the inspection device impedance measurement value; and
calibrating the first detecting unit using a difference between the ECU impedance measurement value and the inspection device impedance measurement value, as a calibration value.

2. The calibration method according to claim 1, wherein the first high-frequency signal supplying unit supplies the first high-frequency signal of 0.5 MHz or higher to the lithium-ion secondary battery.

3. The calibration method according to claim 1, wherein
the lithium-ion secondary battery includes a plurality of battery cells, the calibration method further comprising:
acquiring the ECU impedance measurement value using the battery ECU, in the shipping inspection process for the lithium-ion secondary battery, by the first high-frequency signal supplying unit supplying the first high-frequency signal to at least one battery cell among the battery cells, and the first detecting unit detecting the value of the real part of the alternating current impedance of the at least one battery cell; and
acquiring the inspection device impedance measurement value using the inspection device, by detecting the value of the real part of the alternating current impedance of the at least one battery cell.

4. The calibration method according to claim 1, wherein
the lithium-ion secondary battery includes a plurality of battery cells, the calibration method further comprising:
acquiring the inspection device impedance measurement value using the inspection device, in the shipping inspection process for the lithium-ion secondary battery, by acquiring the ECU impedance measurement value using the battery ECU, through applying electricity to the battery cells such that a voltage value of the battery cells is within a predetermined range.

5. The calibration method according to claim 1, further comprising acquiring the ECU impedance measurement value, in the shipping inspection process for the lithium-ion secondary battery, by supplying an alternating current signal, that is a test signal generated by a three-phase inverter, to the lithium-ion secondary battery in accordance with a particular switching pattern for supplying to the lithium-ion secondary battery, while using the battery ECU to detect the value of the real part of the alternating current impedance of the lithium-ion secondary battery.
